(19) United States
(12) Patent Application Publication
(10) Pub. No.: US 2026/0324346 A1
(43) Pub. Date: Oct. 15, 2026

(54) HEATING POWER CONTROL FOR SEMICONDUCTOR STRUCTURE PROCESSING

(71) Applicant: ASM IP Holding B.V., Almere (NL)

(72) Inventor: Brendan Timothy Padraig Marozas, Leuven (BE)

(21) Appl. No.: 19/641,815

(22) Filed: Apr. 8, 2026

Related U.S. Application Data
(60) Provisional application No. 63/787,164, filed on Apr. 11, 2025.

(51) Int. Cl. H10P 72/00; C23C 16/455; C23C 16/458; C23C 16/48

(52) U.S. Cl. CPC H10P 72/0602; C23C 16/45557; C23C 16/4586; C23C 16/482

(57) ABSTRACT

Methods, apparatuses, and systems, are disclosed for controlling the amount of power used by various heating sources during semiconductor structure processing. The methods/apparatus/systems disclosed perform, for example, heating, using a first heating source, a semiconductor structure disposed on a susceptor within a reactor chamber of an epitaxial reactor system, heating, using a second heating source, the susceptor, and controlling, based on stored data, at least one of a first power of the first heating source or a second power of the second heating source.

### CROSS-REFERENCE TO RELATED APPLICATIONS

This application claims priority to U.S. Provisional Patent Application Ser. No. 63/787,164 filed Apr. 11, 2025 and titled HEATING POWER CONTROL FOR SEMICONDUCTOR STRUCTURE PROCESSING, the disclosure of which is hereby incorporated by reference in its entirety.

### FIELD

The present disclosure relates generally to the field of semiconductor structure processing methods and systems and to the field of device and integrated circuit manufacture. More particularly the present disclosure generally relates to controlling heating source power during semiconductor structure processing.

### BACKGROUND

With advancements in semiconductor technology, precise control of temperature during semiconductor manufacturing processes can be increasingly important. For example, complementary metal-oxide semiconductor (CMOS) integration schemes can use advanced integration schemes involving device-stacking, burying power rails, creating high k/metal gates, creating a source/drain contact layer, and the like. Producing the source/drain layer, for example, relies on a deposition process that is highly selective against dielectrics, often imposing a very narrow “selectivity window” of temperature distribution across the wafer being processed. The temperature should ideally be extremely uniform across the entire wafer, often on the order of 500 degrees Celsius. However, temperature uniformity is difficult to achieve.

Typically, a semiconductor wafer rests upon a susceptor within a reactor chamber. Both the wafer and the susceptor are then heated to a target temperature. Typically, a lamp above the semiconductor wafer irradiates the top of the wafer, and another lamp below the susceptor irradiates the bottom of the susceptor. Thus, the wafer is heated directly by the radiation from above, and the bottom of the wafer receives heat from the heated susceptor. Ideally, the top and bottom of the wafer would be heated at an equal rate and to an equal temperature. But, in practice, this is not easy to do. Practically speaking, the radiation fields from the lamps are not perfectly uniform, the susceptor may not transfer heat uniformly to all parts of the wafer resting thereon, and gases that flow through the reactor chamber can transfer heat energy from one location to another within the chamber.

To counter some of these problems, the susceptor typically rotates, thereby also rotating the semiconductor wafer along with it, in an attempt to average out any non-uniformities within the chamber. This can help produce a more uniform temperature distribution in the semiconductor wafer, thereby also producing a more uniform layer on the wafer. While rotation can produce non-uniformity that sometimes has radial symmetry, radially asymmetric non-uniformity in temperature (and thus in layer thickness and quality) can still be experienced. Radial symmetry refers to symmetry around a central point. For example, for a circular shape having a property that is radially symmetric, dividing the circle into appropriate equally-sized wedges extending out from the center (like slicing a pie), each wedge would have the same value(s) of that property; each wedge would have the same distribution of that property. Examples of radially-symmetric objects include an idealized starfish and many types of flowers. Other techniques for reducing temperature non-uniformities include defining individually adjustable temperature zones and adjusting gas flow within the reaction chamber. However, such techniques still do not adequately address certain temperature non-uniformities such as radially asymmetric temperature non-uniformities.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to processing a semiconductor structure, such as a semiconductor wafer, by at least heating the semiconductor structure and the susceptor on which it is disposed using top/bottom heating power that are selected to potentially increase layer growth uniformity on the semiconductor structure.

In accordance with examples of the disclosure, a reactor system, such as an epitaxial reactor system, is disclosed that comprises a reactor chamber, a gas delivery system, a first heating source, and a second heating source. The reactor chamber may comprise at least one receiving area configured to receive a susceptor. The gas delivery system may be configured to deliver precursor gases within the reactor chamber. The first heating source may be configured to heat a semiconductor structure disposed on the susceptor, and the second heating source may be configured to heat the susceptor. The epitaxial reactor system may further comprise one or more processors, as well as memory storing instructions that, when executed by the one or more processors, cause the epitaxial reactor system to store data associated with heating power delivery, and control, based on the data, at least one of a first power of the first heating source or a second power of the second heating source.

In accordance with examples of the disclosure, methods are disclosed that comprise heating, using a first heating source, a semiconductor structure disposed on a susceptor within a reactor chamber of an epitaxial reactor system; heating, using a second heating source, the susceptor; and control, based on stored data, at least one of a first power of the first heating source or a second power of the second heating source.

In accordance with examples of the disclosure, a non-transitory computer-readable medium storing instructions and data is disclosed. The instructions, when executed, may configure an epitaxial reactor system to cause a first heating source to heat a semiconductor structure disposed on a susceptor within a reactor chamber of an epitaxial reactor system; cause a second heating source to heat the susceptor; and control, based on the data, at least one of a first power of the first heating source or a second power of the second heating source

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 is a schematic diagram of an example semiconductor device manufacturing system, in accordance with one or more embodiments of the disclosure.

FIG. 2 is a schematic diagram of the example semiconductor device manufacturing system of FIG. 1, showing other details in accordance with one or more embodiments of the disclosure.

FIG. 3 is an overhead view of an example susceptor holding multiple semiconductor structures, in accordance with one or more embodiments of the disclosure.

FIG. 4 is a schematic diagram of a controller of the system of FIG. 2, in accordance with one or more embodiments of the disclosure.

FIG. 5 is a flow chart for controlling heating powers during semiconductor structure processing, in accordance with one or more embodiments of the disclosure.

FIG. 6 is another flow chart for controlling heating powers during semiconductor structure processing, in accordance with one or more embodiments of the disclosure.

FIG. 7 is a flow chart showing example implementation details of a step of FIG. 6, in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. The substrate can include various topologies, such as gaps, including recesses, lines, trenches or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, the term “layer” can refer to any continuous or non-continuous structure and material. For example, a layer can include two-dimensional materials, three-dimensional materials, nanoparticles or even partial or full molecular layers or partial or full atomic layers or clusters of atoms and/or molecules. A layer may comprise material or a layer with pinholes, which may be at least partially continuous.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

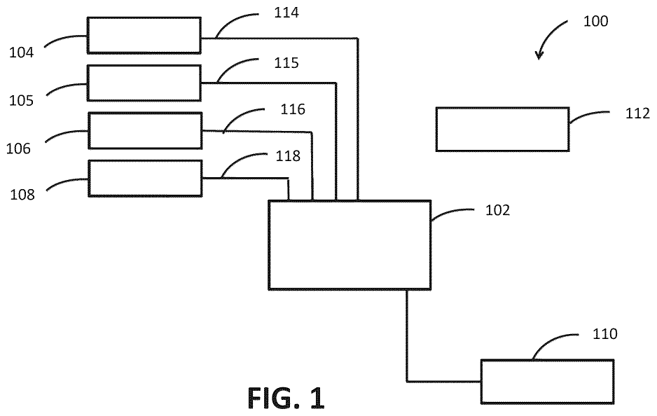

Turning now to the figures, FIG. 1 is a schematic of a system 100 that comprises one or more reactor chambers 102, and a gas delivery system comprising a first precursor gas source 104, a second precursor gas source 105, a reactant gas source 106, a purge gas source 108, and an exhaust 110. The system 100 may further comprise a controller 112. The system 100 may comprise, for example, an epitaxial reactor system.

The one or more reactor chambers 102 may each include any suitable reactor chamber, such as an ALD or CVD reactor chamber.

The first precursor gas source 104 may include a vessel containing one or more precursors as described herein-alone or mixed with one or more carrier gases. Each of the one or more carrier gases may be any kind of gas. For example, each of the one or more carrier gases may be a reactive gas or a noble gas. For example, each of the one or more carrier gases may be a gas such as H2, N2, or a noble gas. The second precursor gas source 105 may comprise a vessel containing one or more reactants as described herein-alone or mixed with one or more carrier gases.

The purge gas source 108 may comprise a vessel containing one or more gases such as noble gases or other purge gases. Although the gas delivery system of system 100 is illustrated with four gas sources 104-108, the system 100 may include any suitable number of gas sources. The gas sources 104-108 may be physically coupled to the one or more reactor chambers 102 via gas lines 114-118, which may each include flow controllers, valves, heaters, and/or the like. The exhaust 110 may comprise a vacuum system that comprises one or more vacuum pumps for adjusting the pressure within the one or more reactor chambers 102.

The controller 112 may comprise electronic circuitry, FPGAs, ASICs, processors, memory storing computer-executable instructions (e.g., software or firmware), data, and/or other components configured to selectively operate valves, manifolds, heaters, pumps and other components included in the system 100.

Other configurations of the system 100 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the one or more reactor chambers 102. As FIG. 1 is a schematic representation of a system, many components have been omitted in the drawing for simplicity of illustration; such components may include, for example, various valves, manifolds, purifiers, heaters, containers, vents, and/or bypasses.

During operation of the reactor system 100, substrates, such as semiconductor wafers (not illustrated), may be transferred from, e.g., a substrate handling system to the one or more reactor chambers 102. Once substrate(s) are transferred to a reactor chamber of the one or more reactor chambers 102, one or more gases from the gas sources 104-108, such as precursors, reactants, carrier gases, and/or purge gases, are introduced into the reactor chamber 102.

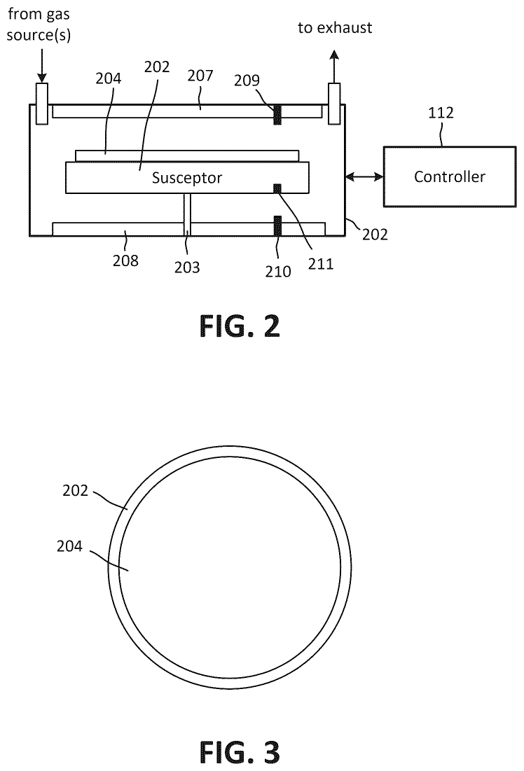

Referring to FIG. 2, the reactor chamber 102 may comprise a holder for a susceptor 202, which may be configured to rotate around an axle 203 powered by an electric motor. The susceptor 202 may be configured to carry thereon a semiconductor wafer 204 or other semiconductor structure, such that the semiconductor wafer 204 rotates with the susceptor. The reactor chamber 102 may further comprise a plurality of heating sources for heating up the susceptor 202 and the semiconductor wafer 204. For example, a heating source 207 may be disposed over the semiconductor wafer 204 and configured to provide heat energy directly or indirectly to the semiconductor wafer 204, and another heating source 208 may be disposed underneath the susceptor 202 and configured to provide heat energy directly or indirectly to the susceptor 202. The controller 112 may control how much power is provided to each of the heating sources. The reactor chamber 102 may further comprise a plurality of temperature sensors. For example, at least one temperature sensor 209 may be configured to directly or indirectly measure a temperature of at least a portion of the semiconductor wafer 204, and at least one temperature sensor 210 may be configured to directly or indirectly measure a temperature of at least a portion of the susceptor 202. There may be multiple temperature sensors configured to measure multiple different portions of the semiconductor wafer 204 and the susceptor 202. For example, temperature sensor 210 may remotely measure a temperature of a particular portion of the susceptor 202, such as a ring-shaped area of the susceptor 202, and another temperature sensor 211 may be directly embedded in or otherwise attached to the susceptor 202 to measure a local temperature at the position of the temperature sensor 211. Each of the temperature sensors may provide a signal, such as data, to the controller 112.

FIG. 3 shows a top view of the semiconductor wafer 204 resting on the susceptor 202. While both structures are shown as having a circular shape, this is by way of example only and each structure 202, 204 may be of any shape desired.

The heating sources may serve to heat both the semiconductor wafer 204 and the susceptor 202 at the same time. A goal of the heating may be to heat the semiconductor wafer 204 from both a top side (facing away from the susceptor 202) and from a bottom side of the semiconductor wafer 204 (facing toward the susceptor 202). To accomplish this, the top side of the semiconductor wafer 204 may be heated remotely using radiant heat, and the bottom side of the semiconductor wafer 204 may be heated conductively from the heated susceptor 202. Each of the heating sources 207 and 208 may comprise one or more heating devices, for example, one or more lamps such as infrared lamps, one or more resistive heaters, and/or one or more inductive heaters. Each of the heating sources 207 and 208 may have a power that is adjustable by the controller 112. For example, the controller 112 may control the heating source 207 to provide a first amount of power (e.g., power of the heat generated by the heating source 207), and may control the heating source 208 to provide a second amount of power (e.g., power of the heat generated by the heating source 208). The controller 112 may control the powers of the heating sources 207, 208 by, for example, controlling how much electrical power is provided to each of the heating sources 207, 208, and/or sending signals to the heating sources 207, 208 indicating or otherwise controlling an amount of heat to be produced.

The rotation of the susceptor 202 and the semiconductor wafer 204 within the reactor chamber 102 may help to average out any differing conditions (e.g., temperature, gas flow, and/or heating) during semiconductor wafer 204 processing that may exist in different locations throughout the reactor chamber 102. For example, different amounts of heating and/or gas flow experienced by different points on the top surface of the semiconductor wafer 204 may affect one or more properties of the semiconductor wafer 204, such as the thickness of a layer being grown on the top of the semiconductor wafer 204. While the rotation may average the conditions in the reactor chamber to a certain extent for any given point on the semiconductor wafer 204, in practice the rotation may not necessarily address all inconsistent conditions experienced by the semiconductor wafer 204 during processing. Such rotation may result in a semiconductor wafer 204 having one or more properties, such as layer thickness, that are radially asymmetric. For example, the layer thickness may be influenced by growth rate, which may be influenced by applied heat during processing. Because rotation of the semiconductor wafer 204 during processing still can result in the semiconductor wafer 204 having radially asymmetric properties, there may be one or more environmental conditions experienced by a given point of the semiconductor wafer 204 are “fixed” despite its rotation.

For example, the susceptor 202 may itself have inconsistencies in material density and/or thickness, and so different portions of the susceptor 202 may conduct heat from the bottom of the susceptor 202 to the top of the susceptor 202 (toward the semiconductor wafer 204) at different rates. Such inconsistencies may cause the semiconductor wafer 204 to be heated by different amounts at different locations of the semiconductor wafer 204. Because the susceptor 202 may rotate at the same rotational speed as the semiconductor wafer 204, such inconsistencies in the susceptor 202 may be positionally “fixed” with respect to the semiconductor wafer 204 despite the rotation. In other words, such inconsistencies in the susceptor 202 would rotate with the rotation of the susceptor 202, and thus any temperature variations caused by variations in the susceptor 202 itself would not be expected to average out due to the rotation.

While more effort might be put into producing susceptors that are more uniform, this can be impractical due to the likely added expense of doing so. Moreover, even if susceptors could be produced with less variation in thickness and material, susceptors typically have wafer lift pins that are useful for allowing a semiconductor wafer to be carefully placed onto and removed from the top of the susceptor. These lift pins, or at least the interface between the lift pins and the main body of the susceptor, may inherently introduce some variability in heat conduction by the susceptor near the lift pins. Indeed, it has been observed that regions of a susceptor near the lift pins have lower thermal conductivity. Thus, it may be impractical to materially reduce radial asymmetry by improving susceptor manufacturing techniques.

It has been further observed that the relative amounts of heat applied to the susceptor 202 and to the semiconductor wafer 204 may also affect radial asymmetry of the semiconductor wafer 204. For heat that is applied by a bottom heating source (e.g., heating source 208) that provides heat to the bottom surface of a susceptor, the temperature of the wafer surface applied by that bottom heat is influenced by thermal transport upward from the bottom of the susceptor. If there is a region of the susceptor with lower thermal conductivity, the wafer surface above this region may be colder based on this applied upward heat and result in a locally slower growth rate. For heat that is applied by a top heating source (e.g., heating source 207) that provides heat to the top of the semiconductor wafer, the temperature of the wafer surface is influenced by thermal transport downward to the bottom of the susceptor. In this case, the temperature of the wafer surface above the region of lower thermal conductivity of the susceptor may be hotter based on this applied downward heat and result in a locally faster growth rate. Thus, there may be a ratio of the top-down heat and the bottom-up heat that may produce better results by balancing the slow-growth influence and the fast-growth influence that occurs in a semiconductor wafer over a low-thermal-transport region (or other varied region) of a susceptor. Put differently and referring again to FIG. 2, the uniformity of the semiconductor wafer 204 after processing may be improved by tuning a ratio of the power applied by the top heating source 207 versus the power applied by the bottom heating source 208. The particular ratio used may depend on a variety of factors, such as the particular processing recipe used (including temperature, gases, pressure, rotation speed, and time), the properties of the susceptor 202, the properties of the semiconductor wafer 204, and/or the type of layer being formed on the semiconductor wafer 204 during processing.

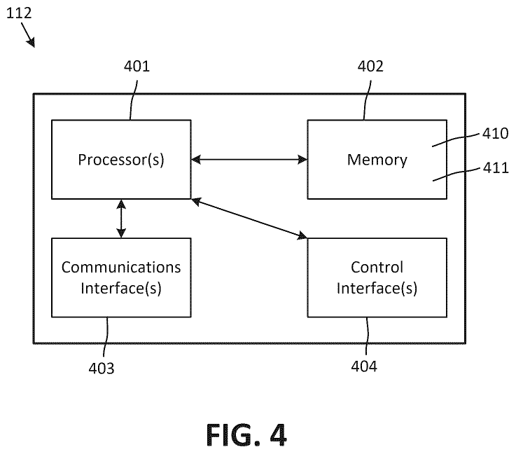

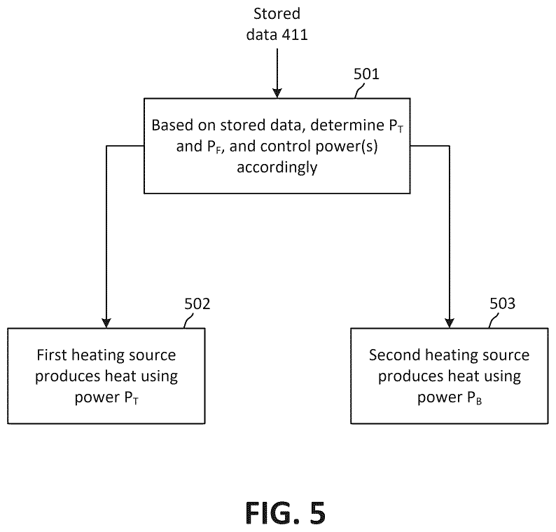

Referring to FIG. 4, the controller 112 of system 100 may comprise, for example, one or more processors 401 and memory 402. Memory 402 may store computer-executable instructions 410 and/or data 411. The computer-executable instructions 410, when executed by the one or more processors 401, may cause the system 100 (e.g., under the control of the controller 112) to perform any of the functions and operations thereof as described herein, including but not limited to the steps and functionality described herein and shown in FIGS. 5, 6, and 7. For example, the controller 112 may operate to introduce precursors and purge gases from the respective gas sources 104-108. The controller 112 may control timing of gas sequences, temperature of the one or more reactor chambers 102 and/or of the substrate therein, pressure within the reactor chamber 102, power to the heating sources 207, 208, and/or various other operations to provide proper operation of the system 100. The controller 112 may electrically and/or pneumatically control valves to control flow of precursors, reactants and purge gases into and out of the one or more reactor chambers 102. Physical control of these characteristics of system 100 may be performed via one or more control interfaces 404, which may be connected to the various other parts of system 100 via one or more electrical and/or pneumatic lines.

The controller 112 of system 100 may further comprise one or more communications interfaces 403. A communications interface may provide, for example, a user interface to receive user input and/or to provide information to a user and/or to another device. For example, the one or more communications interfaces 403 may comprise a keyboard, a mouse, a display, a speaker, a universal serial bus (USB) interface, a serial bus interface, another type of wired communications interface, and/or a wireless communications interface.

As discussed above, the ratio of top power and bottom power (which may be a ratio of top power to bottom power, or a ratio of bottom power to top power) may affect symmetry of the produced semiconductor wafer structure. Experiments carried out by the inventors show that non-uniformity (NU) of an example semiconductor wafer is affected depending upon the ratio of top heating lamp power (TL) to bottom heating lamp power (BL). While heating lamps were used in these experiments, a similar result may be expected for any type of heating source. A NU measurement with varying TL/BL ratios was performed around sample annular strips with different inner radius (“circumferential samples”) of the semiconductor wafer. The results show that a minimum NU value can be found for each circumferential sample. Under the experimental conditions of this experiment, the minimums corresponded to a TL/BL ratio in the range of about 2 to about 3. Thus, for this particular example, using a TL/BL ratio in the range of about 2 to about 3 would be expected to result in a lower NU for the semiconductor wafer at least within the sampled annular strips, and by extension likely across the entire semiconductor wafer. In other words, such a TL/BL ratio may result in the processed semiconductor wafer having improved radial symmetry. This is but one example that involves a particular set of conditions, for example a particular semiconductor wafer, a particular susceptor, and a particular processing recipe. It may be expected that the optimal TL/BL ratio for lowest NU would differ under different conditions, but a similar method to identify said optimal ratio may be applied.

FIG. 5 is an example flow chart showing steps that may be performed to control the power of one or more heating sources during semiconductor wafer processing. The steps of FIG. 5 may be performed and/or controlled by, for example, the controller 112. For example, controller 112 may execute instructions such as instructions 410 stored in memory 402. At step 501, the controller 112 may obtain data that has been previously stored, such as data 411 in memory 402. The stored data 411 may have been provided from user input or from another device into the one or more communications interface 403, and stored in memory 402. The stored data 411 may represent information associated with power of the top heating source 207 and/or of the bottom heating source 208. For example, the stored data 411 may indicate or otherwise be used to determine a target relationship between (for example, a ratio of) top heating source 207 power and bottom heating source 208 power. Where the target relationship is a ratio of the top heating source 207 power (P_{T}) to the bottom heating source 208 power (P_{B}), such a ratio may be a ratio of P_{T}/P_{B} analogous to the TL/BL ratio discussed above, or a ratio of P_{B}/P_{T}. In other examples, the target relationship may be a range of target ratios. For example the range of target ratios may be a particular target ratio plus or minus a predetermined error. The stored data 411 may additionally or alternatively indicate values of P_{B} and/or P_{T}, such as in watts or kilowatts. The stored data 411 may additionally or alternatively indicate a power factor F. For example, the stored data 411 may indicate the value of P_{T} and the value of F, where P_{B} may be determined as P_{B}=F×P_{T}. Or, the stored data 411 may indicate the value of P_{B} and the value of F, where P_{T} may be determined as P_{T}=F×P_{B}. As another example, stored data 411 may comprise a lookup table with any of the above power-related information, and an index value pointing to a desired portion of the lookup table. Any of the stored data may have been provided from user input or from another device into the one or more communications interface 403, and stored in memory 402.

At steps 502 and 503, the controller 112 may cause a first heating source (such as the top heating source 207) to produce heat using determined power P_{T}, and may further cause a second heating source (such as the bottom heating source 208) to produce heat using determined power P_{B}. Steps 502 and 503 may be performed in parallel (for example, simultaneously). The first heating source may produce heat for a semiconductor structure such as the semiconductor wafer 204, and the second heating source may produce heat for a susceptor such as the susceptor 202.

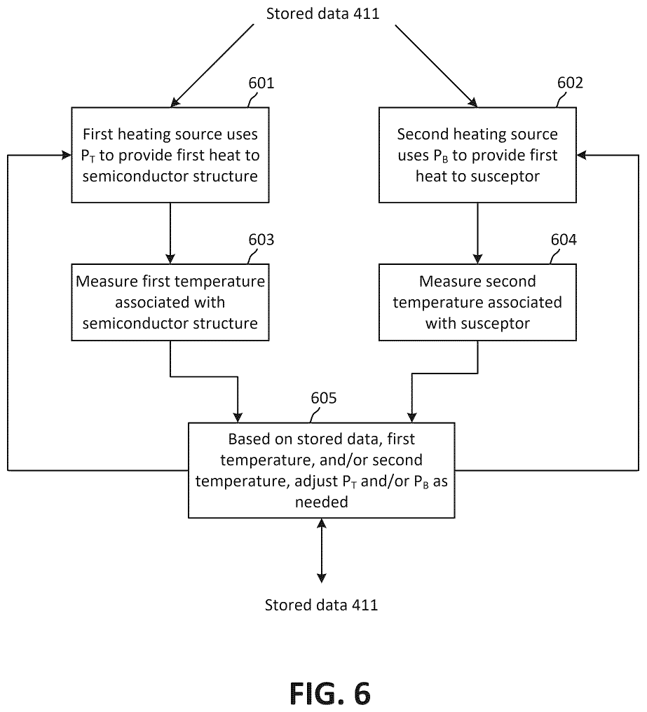

FIG. 6 is another example flow chart showing steps that may be performed to control the power of one or more heating sources during semiconductor wafer processing. The steps of FIG. 6 may be performed and/or controlled by, for example, the controller 112. For example, controller 112 may execute instructions such as instructions 410 stored in memory 402. At step 601, a first heating source (such as the top heating source 207) may produce heat using a power P_{T} to provide heat to a semiconductor structure such as the semiconductor wafer 204. At step 602, a second heating source (such as the bottom heating source 208) may produce heat using a power P_{B} to provide heat to a susceptor such as the susceptor 202. The initial values of P_{T} and BP may be determined based on stored data, such as data 411. The data 411 may indicate, for example, the actual values of P_{T} and P_{B}, a ratio between those values, or some other relationship between the values. The data 411 may also indicate one or more target temperatures, such as a target first temperature associated with the semiconductor structure and/or a target second temperature associated with the susceptor. As further examples, the data 411 may indicate a target relationship between the first and second temperatures, such as a target ratio of the temperatures, an indication that the temperatures are to be equal to each other, an indication that the temperatures are to be within a target range of temperatures from each other, a target difference between the temperatures, and/or an indication of a target temperature range within which each of the temperatures is to fall.

Steps 601 and 602 may be performed in parallel (for example, simultaneously). At step 603, and while the heat of steps 601 and 602 is being applied, one or more first sensors may be used to measure a first temperature associated with the semiconductor structure. The one or more first sensors may include, for example, temperature sensor 209. At step 604, and while the heat of steps 601 and 602 is being applied, one or more second sensors may be used to measure a second temperature associated with the susceptor. The one or more second sensors may include, for example, temperature sensor 210 and/or temperature sensor 211. Steps 601 and 602 may be performed in parallel (for example, simultaneously).

At step 605, it may be determined whether the values of P_{T} and/or P_{B} need to be adjusted to maintain the target relationship between the temperatures and/or the powers of the heating sources. The determination may be based on the measured first temperature, the measured second temperature, the current value of P_{T}, the current value of P_{B}, and/or the stored data. For example, at step 605, it may be determined whether the first temperature and the second temperature satisfy the target relationship (indicated by the stored data) between the first temperature and the second temperature. For example, it may be determined whether the first temperature and the second temperature are substantially equal or within a predetermined target range of each other. If so, then the values of P_{T} and P_{B} may remain unchanged. If not, then the value of P_{T} and/or the value of P_{B} may be adjusted. The adjustment may be, for example, to cause the first and second temperatures to be equal to each other or to be within the predetermined range of each other. If an adjustment is made, the amount of adjustment and/or the new value(s) of P_{T} and/or P_{B} may be stored as data 411, such as by updating, supplementing, or replacing some or all of existing data 411. The process may then return to steps 601 and 602 to continue heating using the current values of P_{T} and P_{B}, which as discussed above may have been adjusted.

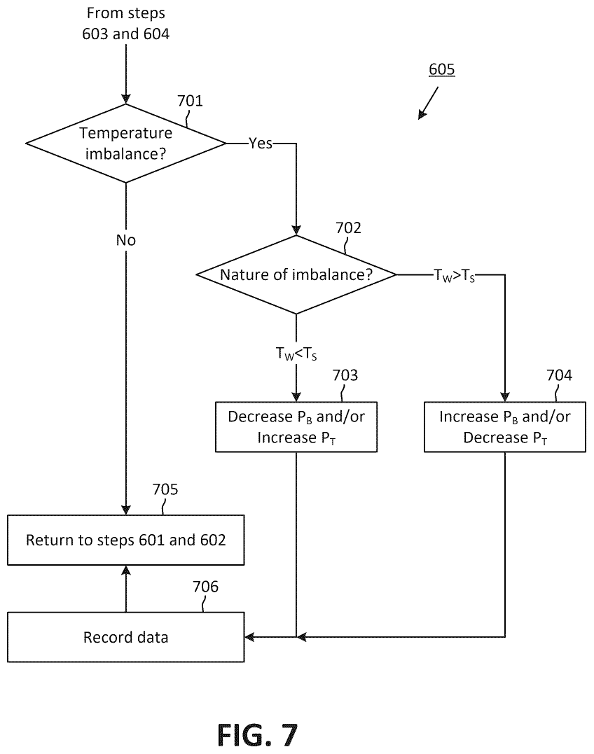

FIG. 7 shows an example of how step 605 may be implemented. In this example, step 605 may comprise steps 701-706. As discussed above, performing steps 603 and 604 results in the measured first and second temperatures. For purposes of FIG. 7, the first temperature associated with the semiconductor structure (e.g., semiconductor wafer) will be referred to as T_{W}, and the second temperature associated with the susceptor will be referred to as T_{S}. At step 701, it may be determined whether there is a temperature imbalance between the first temperature and the second temperature. Determining whether a temperature imbalance exists may be useful, for example, where it is desired that the temperatures of the semiconductor wafer and the susceptor are approximately equalized, at least within a small error range. Equalizing temperatures may result in more even growth of a layer on the semiconductor wafer. One or more criteria may be used to determine whether a temperature imbalance exists. For example, if T_{W} and T_{S} are unequal, or if a difference between T_{W} and T_{S} is greater than a predetermined threshold, then it may be determined that the temperature imbalance exists. On the other hand, if T_{W} and T_{S} are equal, or if the difference between T_{W} and T_{S} is less than the predetermined threshold, then it may be determined that the temperature imbalance does not exist. As another example, the criteria may comprise a target temperature range or a target ratio of measured temperatures. These are merely some examples of criteria that may be used to determine the existence of temperature imbalance; other one or more criteria may be used.

If it is determined at step 701 that a temperature imbalance does not exist, then the process may move to step 705, which causes the process to return to steps 601 and 602 of FIG. 6. If, however, it is determined at step 701 that a temperature imbalance exists, then the process may move to step 702. At step 702, the nature of the imbalance may be determined. For example, it may be determined which of T_{W} and T_{S} is greater than or lesser than the other. For example, it may be determined whether T_{W} is greater than T_{S} or that T_{S} is greater than T_{W}. Mathematically equivalently, it may be determined whether T_{S} is lesser than T_{W} or that T_{W} is lesser than T_{S}.

For example, if it is determined that T_{W} is lesser than T_{S} (or that T_{S} is greater than T_{W}) then this means that the measured temperature of the semiconductor wafer is lower than the measured temperature of the susceptor. In this case, it may be desirable to raise the temperature of the semiconductor wafer, lower the temperature of the susceptor, or both. In such a situation, the process may move to step 703, in which bottom power P_{B} may be decreased (which would lower the temperature of the susceptor), top power P_{T} may be increased (which would raise the temperature of the semiconductor wafer), or both may be performed.

On the other hand, if it is determined that T_{W} is greater than T_{S} (or that T_{S} is lesser than T_{W}), then this means that the measured temperature of the semiconductor wafer is higher than the measured temperature of the susceptor. In this case, it may be desirable to lower the temperature of the semiconductor wafer, raise the temperature of the susceptor, or both. In such a situation, the process may instead move from step 702 to step 704, in which bottom power P_{B} may be increased (which would raise the temperature of the susceptor), top power P_{T} may be decreased (which would lower the temperature of the semiconductor wafer), or both may be performed.

After the adjustment is made in either step 703 or step 704, the process may move to step 706, in which any adjusted values of P_{B} and/or P_{T} may be recorded, such as in memory 402. The adjusted values may supplement previously-stored power value data or may replace the previously-stored power value data. The process may then move to step 705, which may cause the process to return back to steps 601 and 602 for further temperature measurements. Thus, the process of FIGS. 6 and 7 may be repeated, with repeated temperature measurements and feedback control of power adjustments to equalize temperatures, until the semiconductor processing recipe (or desired portion thereof) is complete.

Once the process of FIGS. 6 and 7 is complete, the memory 402 may thus store data indicating the final adjusted values of P_{B} and P_{T} that result in relatively equalized (or nearly similar) temperatures of the semiconductor structure and the susceptor. This data may be used for initial conditions during a future processing of a semiconductor structure. For example, the final adjusted values of PB and PT may be used as the initial condition data of steps 501, 601, and/or 602. In this way, the process of FIGS. 6 and 7 may be used not only to actually process semiconductor wafers and other semiconductor structures, but also to determine a set point for the bottom and top powers P_{B} and P_{T} for a given semiconductor structure processing recipe. For example, it is expected that equalizing (or approximately equalizing) the bottom and top powers may result in the TL/BL ratio of FIG. 7 to be at or near the minimum NU.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. An epitaxial reactor system comprising:
a reactor chamber comprising at least one receiving area configured to receive a susceptor;
a gas delivery system configured to deliver precursor gases within the reactor chamber;
a first heating source configured to heat a semiconductor structure disposed on the susceptor;
a second heating source configured to heat the susceptor;
one or more processors; and
memory storing instructions that, when executed by the one or more processors, cause the epitaxial reactor system to:
store data associated with heating power delivery; and
control, based on the data, at least one of a first power of the first heating source or a second power of the second heating source.

2. The epitaxial reactor system of claim 1, further comprising a user interface configured to receive user input, wherein the data is based on the user input.

3. The epitaxial reactor system of claim 1, wherein the instructions, when executed by the one or more processors, further cause the epitaxial reactor system to:
determine, based on the data, a target relationship between the first power and the second power; and
control at least one of the first power or the second power by adjusting at least one of the first power or the second power to maintain the target relationship.

4. The epitaxial reactor system of claim 3, wherein the target relationship comprises at least one of:
a target ratio, or a target ratio range, of the first power and the second power; or
a target difference, or a target difference range, between the first power and the second power.

5. The epitaxial reactor system of claim 1, further comprising:
a first sensor configured to measure a first temperature associated with the semiconductor structure; and
a second sensor configured to measure a second temperature associated with the semiconductor structure,
wherein the instructions, when executed by the one or more processors, cause the epitaxial reactor system to:
determine, based on the data, a target relationship between the first temperature and the second temperature; and
control at least one of the first power or the second power by adjusting at least one of the first power or the second power to maintain the target relationship.

6. The epitaxial reactor system of claim 5, wherein the target relationship comprises at least one of:
a target ratio, or a target ratio range, of the first temperature and the second temperature; or
a target difference, or a target difference range, between the first temperature and the second temperature.

7. The epitaxial reactor system of claim 1, further comprising a user interface configured to cause an indication based on the data to be displayed.

8. The epitaxial reactor system of claim 1, further comprising a vacuum system configured to adjust a pressure within the reactor chamber.

9. A method comprising:
heating, using a first heating source, a semiconductor structure disposed on a susceptor within a reactor chamber of an epitaxial reactor system;
heating, using a second heating source, the susceptor; and
control, based on stored data, at least one of a first power of the first heating source or a second power of the second heating source.

10. The method of claim 9, further comprising receiving user input, wherein the data is based on the user input.

11. The method of claim 9, further comprising:
determining, based on the data, a target relationship between the first power and the second power; and
wherein the controlling at least one of the first power or the second power comprises adjusting at least one of the first power or the second power to maintain the target relationship.

12. The method of claim 11, wherein the target relationship comprises at least one of:
a target ratio, or a target ratio range, of the first power and the second power; or
a target difference, or a target difference range, between the first power and the second power.

13. The method of claim 9, further comprising:
measuring a first temperature associated with the semiconductor structure;
measuring a second temperature associated with the semiconductor structure; and
determining, based on the data, a target relationship between the first temperature and the second temperature,
wherein the controlling at least one of the first power or the second power comprises adjusting at least one of the first power or the second power to maintain the target relationship.

14. The method of claim 13, wherein the target relationship comprises at least one of:
a target ratio, or a target ratio range, of the first temperature and the second temperature; or
a target difference, or a target difference range, between the first temperature and the second temperature.

15. The method of claim 9, further comprising causing display of an indication that is based on the data.

16. The method of claim 9, further comprising adjusting a pressure within the reactor chamber.

17. A non-transitory computer-readable medium storing instructions and data, wherein the instructions, when executed, configure an epitaxial reactor system to:
cause a first heating source to heat a semiconductor structure disposed on a susceptor within a reactor chamber of an epitaxial reactor system;
cause a second heating source to heat the susceptor; and
control, based on the data, at least one of a first power of the first heating source or a second power of the second heating source.

18. The non-transitory computer-readable medium of claim 17, wherein the instructions, when executed, further configure the epitaxial reactor system to:
determine, based on the data, a target relationship between the first power and the second power; and
control at least one of the first power or the second power by adjusting at least one of the first power or the second power to maintain the target relationship.

19. The non-transitory computer-readable medium of claim 18, wherein the target relationship comprises at least one of:
a target ratio, or a target ratio range, of the first power and the second power; or
a target difference, or a target difference range, between the first power and the second power.

20. The non-transitory computer-readable medium of claim 17, wherein the instructions, when executed, further configure the epitaxial reactor system to:
measure a first temperature associated with the semiconductor structure;
measure a second temperature associated with the semiconductor structure;
determine, based on the data, a target relationship between the first temperature and the second temperature; and
control at least one of the first power or the second power by adjusting at least one of the first power or the second power to maintain the target relationship.
